(19) United States
(12) Patent Application Publication
(10) Pub. No.: US 2024/0172372 A1
(43) Pub. Date: May 23, 2024

(54) Structures for Forming Printed Board Interconnects Using Solder

(71) Applicant: Conductor Analysis Technologies, Inc., Albuquerque, NM (US)

(72) Inventors: Timothy A. Estes, Albuquerque, NM (US); Lance A. Auer, Dewey, AZ (US); Nicholas J. Meeker, Albuquerque, NM (US)

(73) Assignee: Conductor Analysis Technologies, Inc., Albuquerque, NM (US)

(21) Appl. No.: 18/211,523

(22) Filed: Jun. 19, 2023

Related U.S. Application Data
(60) Provisional application No. 63/353,800, filed on Jun. 20, 2022.

(51) Int. Cl. H05K 3/46; H05K 1/11; H05K 3/00; H05K 3/42

(52) U.S. Cl. CPC H05K 3/4652; H05K 1/115; H05K 3/0047; H05K 3/0094; H05K 3/421; H05K 3/429; H05K 2201/09509

(57) ABSTRACT

Certain exemplary embodiments can provide structures used to form printed board layer-to-layer interconnects using solder. When the structures are laminated together, forming a printed board, the solders fuse or bond to other electrically conductive materials forming layer-to-layer interconnects. Benefits include reduced fabrication time and costs, fewer and simpler process steps, known metallurgy, increased reliability, and a significant reduction in environmental impact.

### CROSS-REFERENCES TO RELATED APPLICATIONS

This application claims priority to, and incorporates by reference herein in its entirety, U.S. Provisional Patent Application Ser. No. 63/353,800 (Attorney Docket No. 1636-01), filed Jun. 20, 2022.

### BRIEF DESCRIPTION OF THE DRAWINGS

The patent or application file contains at least one drawing executed in color. Copies of this patent or patent application publication with color drawings will be provided by the Office upon request and payment of the necessary fee. A wide variety of potential practical and useful embodiments will be more readily understood through the following detailed description of certain exemplary embodiments, with reference to the accompanying exemplary drawings in which:

FIG. 1 is a sectional view of an exemplary embodiment of a printed board 1000;

FIG. 2 is a sectional view of a set of exemplary single sided structures 2000;

FIG. 3 is a sectional view of a set of exemplary double sided structures 3000;

FIG. 4 is a sectional view of a set of exemplary Every-Layer-Interconnect (ELIC) stackups 4000;

FIG. 5 is a sectional view of a set of exemplary High Density Interconnect (HDI) stackups 5000;

FIG. 6 is a sectional view of a set of a board-to-board interconnect stackups 6000;

FIG. 7 is a sectional view of one side of outer layer HDI interconnects 7000;

FIG. 8 is a flowchart of an exemplary embodiment of a method 8000;

FIG. 9 is a sectional view of one side of outer layer HDI over subcomposite interconnects 9000; and

FIG. 10 is a flowchart of an exemplary embodiment of a method 10000.

### DETAILED DESCRIPTION

Certain exemplary embodiments can provide a printed board. The printed board comprises a base material, a dielectric, and a solder. The base material comprises a first side and an opposing second side. The base material comprises a metal clad circuit pattern on at least one of the first side of the base material and the second side of the base material. The dielectric is applied to at least one of the first side of the base material and the second side of the base material.

Certain exemplary embodiments can provide structures used to form printed board layer-to-layer interconnects using solder. When the structures are laminated together, forming a printed board, the solders fuse or bond to other electrically conductive materials forming layer-to-layer interconnects. Benefits include reduced fabrication time and costs, fewer and simpler process steps, straightforward metallurgy, increased reliability, and a significant reduction in environmental impact.

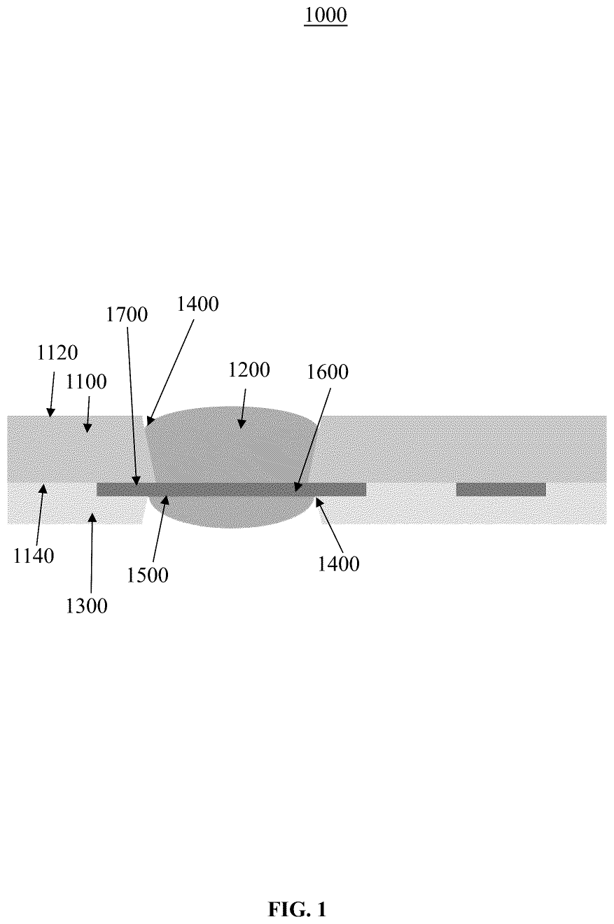

FIG. 1 is a sectional view of an exemplary embodiment of a printed board 1000, which comprises a base material 1100, a solder 1200, a dielectric 1300, and a metal clad circuit pattern 1600. Printed board 1000 defines a via 1400.

Base material 1100 comprises a first side 1120 and an opposing second side 1140. Base material 1100 can comprise and/or be connected to metal clad circuit pattern 1600 on at least one of first side 1120 of base material 1100 and second side 1140 of base material 1100.

Dielectric 1300 can be applied to at least one of first side 1120 of base material 1100 and second side 1140 of base material 1100.

Printed board 1000 defines via 1400. Via 1400 is defined by base material 1100 and dielectric 1300. Via 1400 can be one of a plurality of vias and/or can comprise dielectric 1300. Dielectric 1300 can be adjacent to, and/or electrically coupled to, a metal clad surface 1500 of an interconnect 1700.

Solder 1200 can be applied to base material 1100, dielectric 1300, and metal clad surface 1500 of interconnect 1700. Solder 1200 is bonded mechanically and electrically to the metal clad surface 1500.

When two or more structures of printed board 1000 are laminated at a sufficient temperature; adjacent solders fuse or solders bonds to metal clad surfaces forming printed board layer-to-layer interconnects.

Base material 1100 can comprise and/or be coupled to metal clad circuit pattern 1600 on at least one of the first side 1120 of base material 1100 and the second side 1140 of base material 1100.

Base material 1100 can be physically coupled to dielectric 1300.

FIG. 1 illustrates a single layer embodiment of printed board 1000 for illustrative purposes. Those skilled in the art will recognize the application of coupling a plurality of single layer structures such as printed board 1000 to form complex multi-layer structures.

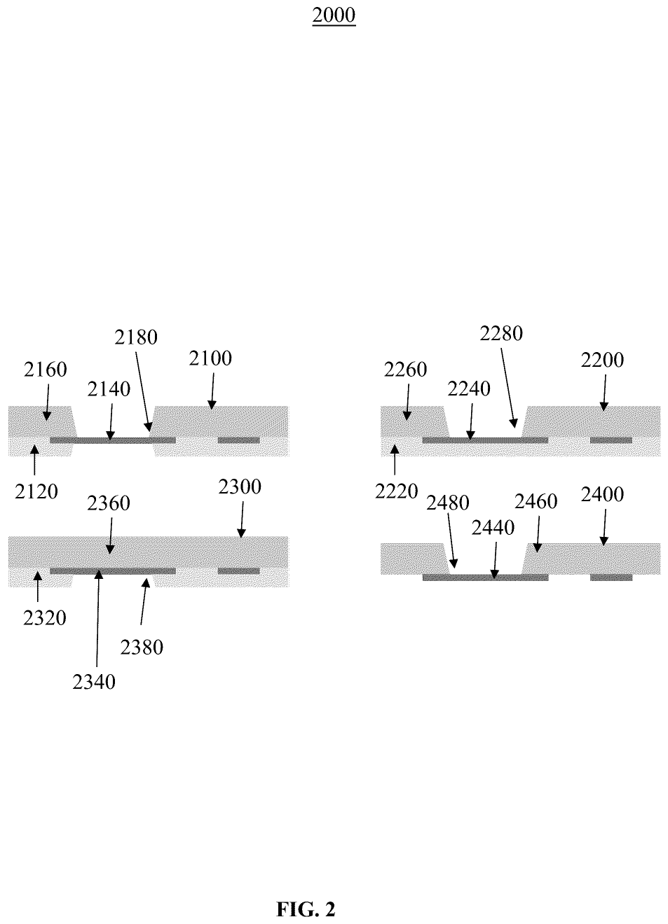

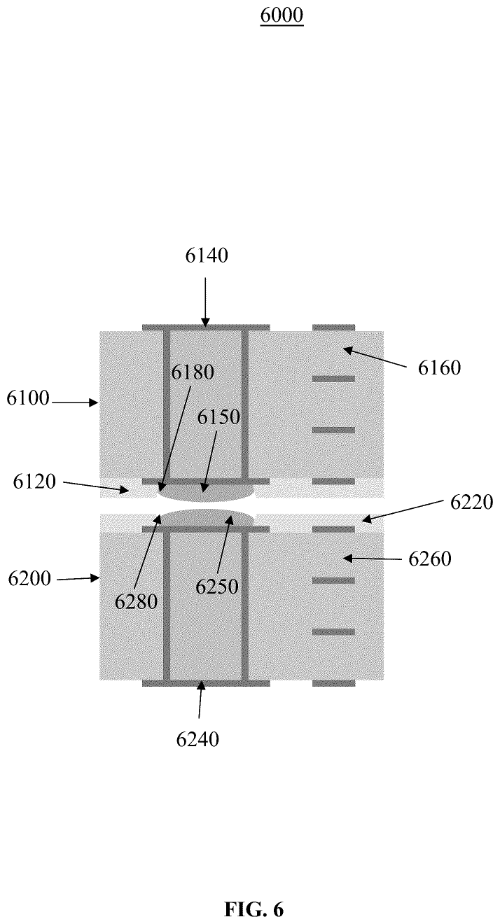

The shading utilized in FIG. 1 is also utilized in each of FIG. 2 through FIG. 6. The shading for:
base material 1100 is also utilized for base materials throughout FIG. 2 through FIG. 6 (see, e.g., base material 6160 of FIG. 6);
solder 1200 is also utilized for solders throughout FIG. 2 through FIG. 6 (see, e.g., solder 6150 of FIG. 6);
dielectric 1300 is also utilized for dielectrics throughout FIG. 2 through FIG. 6 (see, e.g., dielectric 6120 of FIG. 6); and
metal clad circuit pattern 1600 is also utilized for metal clad circuit patterns throughout FIG. 2 through FIG. 6 (see, e.g., metal clad circuit pattern 6140 of FIG. 6).

FIG. 2 is a sectional view of a set of exemplary single sided structures 2000, which comprises a first single sided structure 2100, a second single sided structure 2200, a third single sided structure 2300, and a fourth single sided structure 2400. First single sided structure 2100, second single sided structure 2200, third single sided structure 2300, and fourth single sided structure 2400 are illustrated without solder for illustrative purposes. In operative embodiments, solder can be utilized with any and/or all single sided structures 2000 in order to fuse layers of structures together. Other single or double sided structures can be utilized.

First single sided structure 2100 comprises a base material 2160, a dielectric 2120, and a metal clad circuit pattern 2140. First single sided structure 2100 defines a via 2180.

Second single sided structure 2200 comprises a base material 2260, a dielectric 2220, and a metal clad circuit pattern 2240. Second single sided structure 2200 defines a via 2280.

Third single sided structure 2300 comprises a base material 2360, a dielectric 2320, and a metal clad circuit pattern 2340. Third single sided structure 2300 defines a via 2380.

Fourth single sided structure 2400 comprises a base material 2460 and a metal clad circuit pattern 2440. Fourth single sided structure 2400 defines a via 2380.

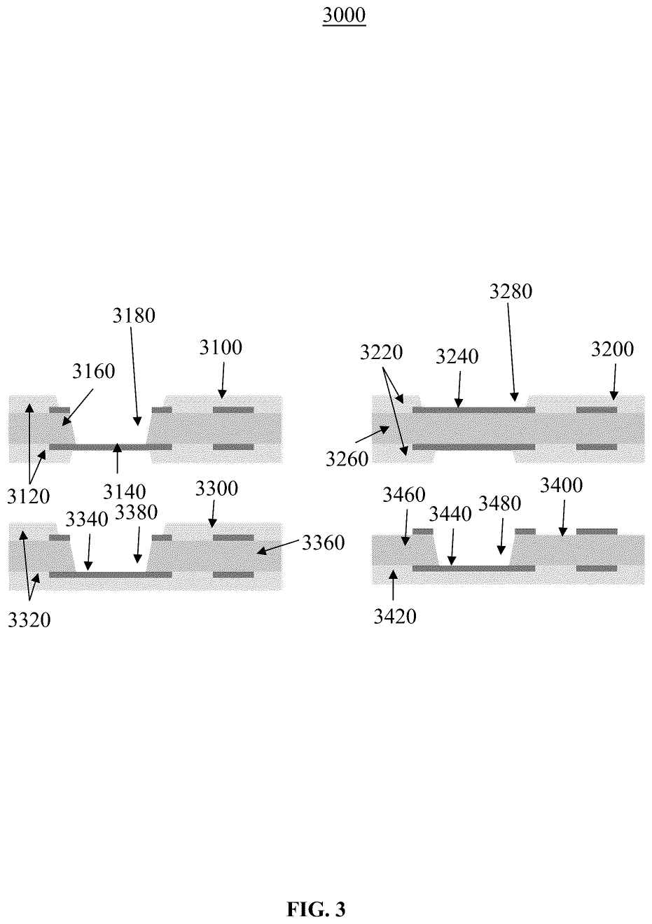

FIG. 3 is a sectional view of a set of exemplary double sided structures 3000, which comprises a first double sided structure 3100, a second double sided structure 3200, a third double sided structure 3300, and a fourth double sided structure 3400. First double sided structure 3100, second double sided structure 3200, third double sided structure 3300, and fourth double sided structure 3400 are illustrated without solder for illustrative purposes. In operative embodiments, solder can be utilized with any and/or all double sided structures 3000 in order to fuse layers of structures together. Other single or double sided structures can be utilized.

First double sided structure 3100 comprises a base material 3160, a dielectric 3120, and a metal clad circuit pattern 3140. First double sided structure 3100 defines a via 3180.

Second double sided structure 3200, comprises a base material 3260, a dielectric 3220, and a metal clad circuit pattern 3240. Second double sided structure 3200 defines a via 3280.

Third double sided structure 3300 comprises a base material 3360, a dielectric 3320, and a metal clad circuit pattern 3340. Third double sided structure 3300 defines a via 3380.

Fourth double sided structure 3400 comprises a base material 3460, a dielectric 3420, and a metal clad circuit pattern 3440. Fourth double sided structure 3400 defines a via 3480.

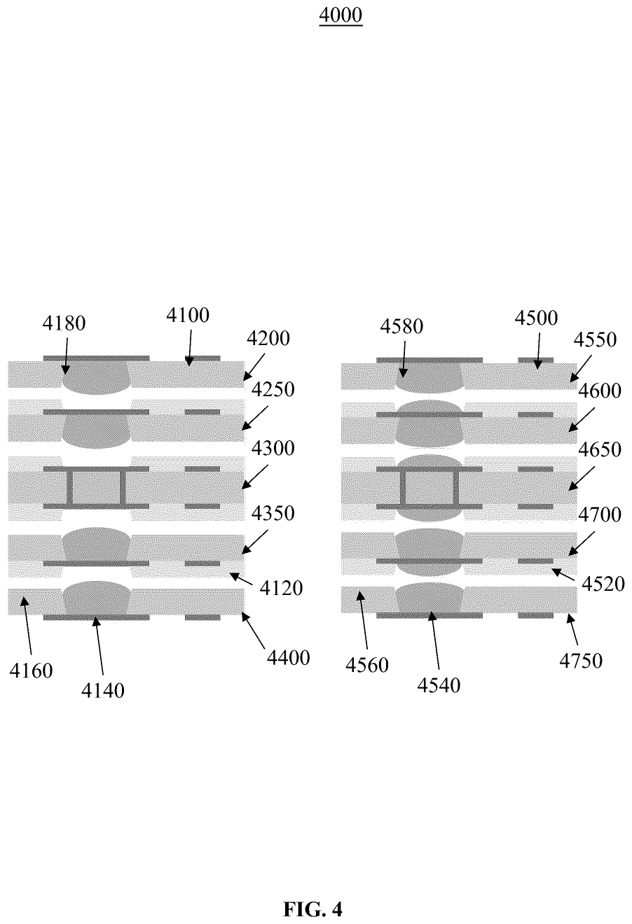

FIG. 4 is a sectional view of a set of exemplary pre-lamination stackups 4000, which comprises a first pre-lamination stackup 4100 and a second pre-lamination stackup 4500. First pre-lamination stackup 4100 comprises a first printed circuit board 4200, a second printed circuit board 4250, a third printed circuit board 4300, a fourth printed circuit board 4350, and a fifth printed circuit board 4400. First pre-lamination stackup 4100 is illustrative of every-layer-interconnect (“ELIC”) technology. First printed circuit board 4200, second printed circuit board 4250, fourth printed circuit board 4350, and fifth printed circuit board 4400 as illustrated each have a single sided structure with solder applied to one side of each interconnect. Third printed circuit board 4300 is a double sided structure and is positioned as a core of first pre-lamination stackup 4100.

First printed circuit board 4200, second printed circuit board 4250, third printed circuit board 4300, fourth printed circuit board 4350, and/or fifth printed circuit board 4400 can comprise a base material 4160, a dielectric 4120, and/or a metal clad circuit pattern 4140. First printed circuit board 4200, second printed circuit board 4250, third printed circuit board 4300, fourth printed circuit board 4350, and/or fifth printed circuit board 4400 can define a via 4180.

Second pre-lamination stackup 4500 comprises a sixth printed circuit board 4550, a seventh printed circuit board 4600, an eighth printed circuit board 4650, a ninth printed circuit board 4700, and a tenth printed circuit board 4750. Second pre-lamination stackup 4500 is illustrative of ELIC technology. Sixth printed circuit board 4550, seventh printed circuit board 4600, ninth printed circuit board 4700, and tenth printed circuit board 4750 as illustrated each have a single sided structure with solder applied to one side of each interconnect. Eighth printed circuit board 4650 is a double sided structure and is positioned as a core of second pre-lamination stackup 4500.

Sixth printed circuit board 4550, seventh printed circuit board 4600, eighth printed circuit board 4650, ninth printed circuit board 4700, and/or tenth printed circuit board 4750 can comprise a base material 4560, a dielectric 4520, and/or a metal clad circuit pattern 4540. Sixth printed circuit board 4550, seventh printed circuit board 4600, eighth printed circuit board 4650, ninth printed circuit board 4700, and/or tenth printed circuit board 4750 can define a via 4180.

The arrangements illustrated in pre-lamination stackups 4000 are spaced for illustrative purposes. The stackups will be compressed and heated to form an integrated single printed circuit board.

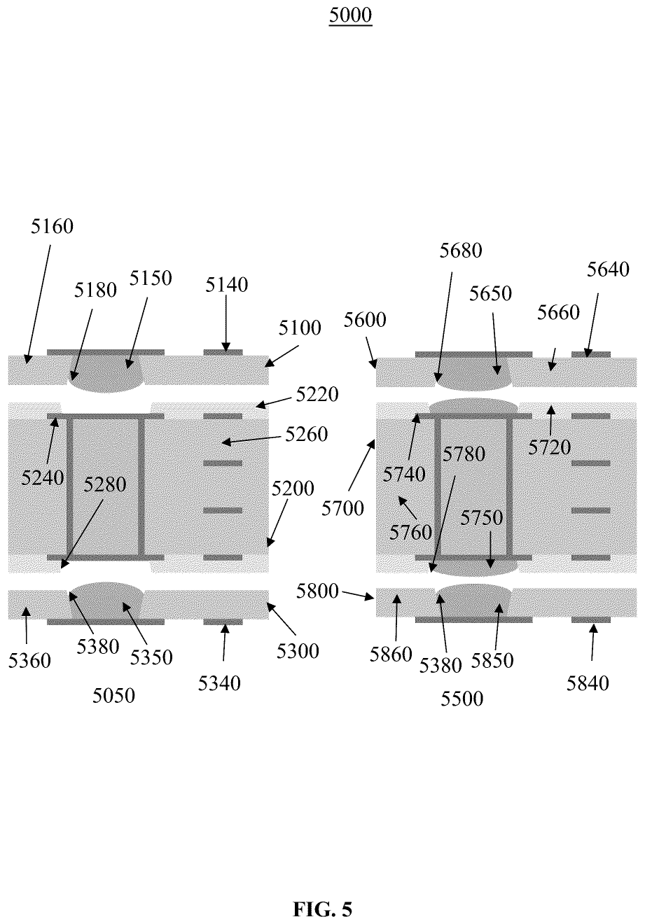

FIG. 5 is a sectional view of a set of exemplary HDI stackups 5000, which comprises a first HDI stackup 5050, and a second HDI stackup 5500. First HDI stackup 5050 comprises a first HDI board 5100, a second HDI board 5200, and a third HDI board 5300. First HDI stackup 5050 is illustrative of an embodiment that utilizes HDI technology. Solder is illustrated on single sides of interconnects. Other embodiments can comprise solder on both sides of interconnects. Second HDI board 5200 forms a multilayer printed board center core of first HDI stackup 5050.

First HDI board 5100 comprises a base material 5160, solder 5150, a metal clad circuit pattern 5140. First HDI board 5100 defines a via 5180.

Second HDI board 5200 comprises a base material 5260, a dielectric 5220, and a metal clad circuit pattern 5240. Second HDI board 5200 defines a via 5280.

Third HDI board 5300 comprises a base material 5360, solder 5350, a metal clad circuit pattern 5340. Third HDI board 5300 defines a via 5380.

Second HDI stackup 5500 comprises a fourth HDI board 5600, a fifth HDI board 5700, and a sixth HDI board 5800. Second HDI stackup 5500 is illustrative of an embodiment that utilizes HDI technology. Solder is illustrated on both sides of certain interconnects. Other embodiments can comprise solder on a single side of interconnects. Fifth HDI board 5700 forms a multilayer printed board center core of second HDI stackup 5500.

Fourth HDI board 5600 comprises a base material 5660, solder 5650, a metal clad circuit pattern 5640. Fourth HDI board 5600 defines a via 5680.

Fifth HDI board 5700 comprises a base material 5760, a dielectric 5720, solder 5750, and a metal clad circuit pattern 5740. Fifth HDI board 5700 defines a via 5780.

Sixth HDI board 5800 comprises a base material 5860, solder 5850, a metal clad circuit pattern 5840. Sixth HDI board 5800 defines a via 5880.

FIG. 6 is a sectional view of a set of a board-to-board interconnect stackup 6000, which comprises a first printed board 6100 and a second printed board 6200. Board-to-board interconnect stackup 6000 utilizes board-to-board interconnect technology. Board-to-board interconnect stackup 6000 illustrates two multilayer printed boards that are coupled together. As illustrated, solder is applied to both sides of illustrated interconnects.

First printed board 6100 comprises a base material 6160, solder 6150, dielectric 6120, and metal clad circuit pattern 6140. First printed board 6100 defines a via 6180.

Second printed board 6200 comprises a base material 6260, solder 6250, dielectric 6220, and metal clad circuit pattern 6240. Second printed board 6200 defines a via 6280.

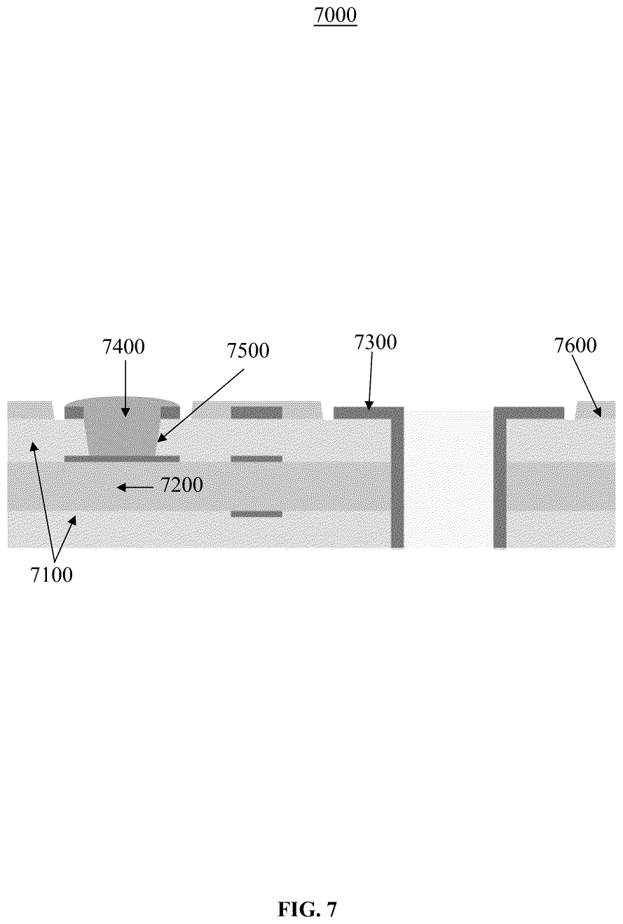

FIG. 7 is a sectional view of one side of outer layer HDI interconnects 7000. Outer layer HDI interconnects 7000 comprises a base material 7200, solder 7400, dielectric 7100, metal clad circuit pattern 7300, and a soldermask 7600. Outer layer HDI interconnects 7000 defines via 7500.

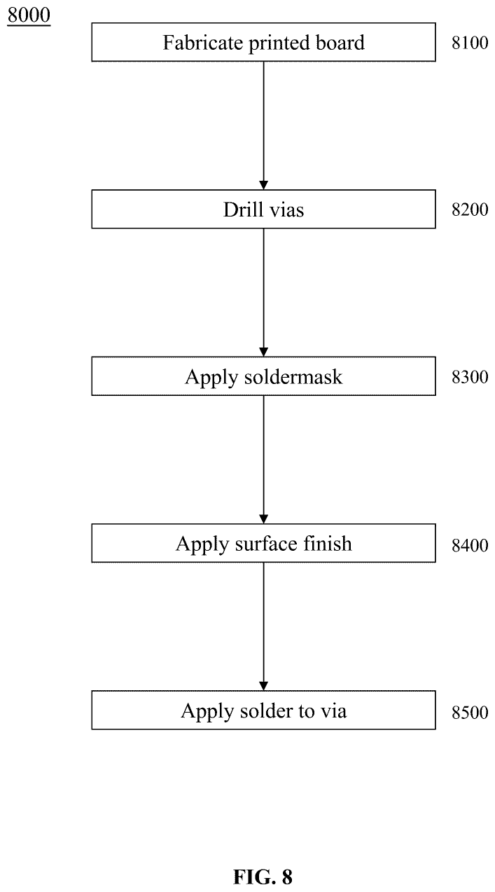

FIG. 8 is a flowchart of an exemplary embodiment of a method 8000. At activity 8100, a printed board is fabricated. In certain exemplary embodiments, the board can be a main printed board (see, e.g., FIG. 7).

At activity 8200, one or more vias are drilled from one or both outer layers of the printed board.

At activity 8300, a soldermask can be applied to the main printed board.

At activity 8400, a surface finish is applied to the main printed board.

At activity 8500, solder is applied to the one or more vias.

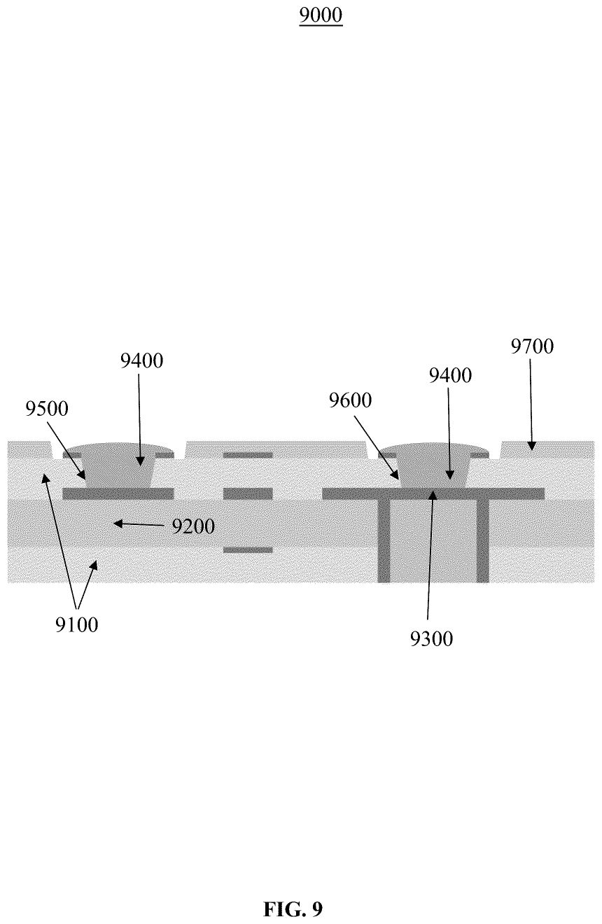

FIG. 9 is a sectional view of one side of outer layer HDI over subcomposite interconnects 9000. Outer layer HDI over subcomposite interconnects 9000 comprises a base material 9200, solder 9400, dielectric 9100, metal clad circuit pattern 9300, and soldermask 9700. Outer layer HDI over subcomposite interconnects 9000 defines a first via 9500 and a second via 9600.

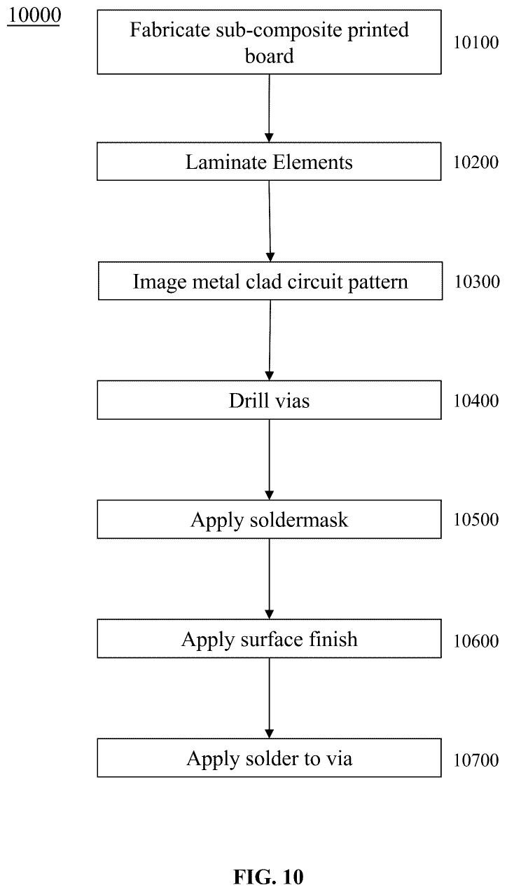

FIG. 10 is a flowchart of an exemplary embodiment of a method 10000. At activity 10100, a printed board is fabricated. In certain exemplary embodiments, the board can be a sub-composite printed board (see, e.g., FIG. 9).

At activity 10200, one or more elements can be laminated. For example, dielectrics and/or metal clad of the printed board can be laminated (see, e.g., FIG. 9).

At activity 10300, an image pattern can be created and/or applied. For example, a circuit pattern image can be applied to one or more metal clad portions of the printed board.

At activity 10400, one or more vias are drilled from one or both outer layers of the printed board.

At activity 10500, a soldermask can be applied to one or more portions of the printed board.

At activity 10600, a surface finish is applied to one or more portions of the printed board.

At activity 10700, solder is applied to the one or more vias. The one or more vias can be completely or partially filled by the solder.

### Definitions

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.
a—at least one.
access—an ability to approach or make contact.
adjacent—lying near to something else.
and/or—either in conjunction with or in alternative to.
apply—to put on a surface.
base material—a rigid and/or flexible insulating material upon which a conductive pattern can be formed.
blind via—an aperture that connects an outer layer with one or more inner layers.
board-to-board—technology via which circuit boards are bonded together.
bond—to join electrically and/or mechanically.
can—is capable of, in at least some embodiments.
circuit—a system that electrically joins electric and/or electronic
components using conductive paths.
clad—comprising a layer of a metal bonded to a surface.
comprising—including but not limited to.
connect—to join or fasten together.
define—to establish the outline, form, or structure of
dielectric—an electrical insulating material used to isolate electrical
layers of a printed board.
directly—substantially without an intervening component or intervening space.
drill—(n) a system constructed to make holes in solid substances; (v) to make an aperture by the process of boring with a bit or laser.
every-layer-interconnect (ELIC)—a high density printed board construction technology.
fabricate—to construct.
finish—a layer of material applied to an outer surface.
form—to create.
fuse—to join by melting together.
heat—to apply energy in a manner that increases a temperature of something.
high density interconnect (“HDI”)—a construction technology that results in one or more build-up layers on either side of a printed board.
interconnect—a structure that electrically joins two or more circuit elements.
join—to link in some fashion.
laminate—to join layers of material together.
layer—a quantity of material placed on the surface of something.
layer-to-layer—between a layer and another layer of an object.
may—is allowed and/or permitted to, in at least some embodiments.
metal—a material that is typically hard, opaque, shiny, and has good electrical and thermal conductivity.
method—a process, procedure, and/or collection of related activities for accomplishing something.
opposing—to be positioned to face something or be on an opposite side of something.
outer—situated to be furthest away from an object center.
pattern—a design of something.
portion—a part of a whole.
printed board—a general term for an interconnect substrate that comprises rigid and/or flexible dielectric materials and two or more conductive layers that have been bonded together and electrically interconnected. Commonly referred to as printed circuit board or integrated circuit package substrate.
side—a bounding portion of an object.
solder—a metal alloy used to form an electrical and mechanical bond between of two or more metal surfaces.
soldermask—a polymer that is usually applied to a printed board to resist oxidation and/or to resist solder bridges formation between solder pads.
structure—something that is created or built.
sub-composite—a layered component positioned under an outer surface.
sufficient—enough in quantity for a certain purpose (e.g., a high enough temperature to fuse or bond materials).
surface—the outer boundary of an object or a material layer.
temperature—a measure of kinetic energy of a substance.
through—moving into and out of something.
transmit—to send, provide, furnish, and/or supply.
via (through, blind or buried)—(n) a hole either coated and/or filled with conductive materials that forms an electrical connection between two or more conductive layers of a printed board.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.

Thus, regardless of the content of any portion (e.g., title, field, background, summary, description, abstract, drawing figure, etc.) of this application, unless clearly specified to the contrary, such as via explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
no characteristic, function, activity, or element is “essential”;
any elements can be integrated, segregated, and/or duplicated;
any activity can be repeated, any activity can be performed by multiple entities, and/or any activity can be performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing figure, etc.) of this application, other than the claims themselves, is to be regarded as illustrative in nature, and not as restrictive, and the scope of subject matter protected by any patent that issues based on this application is defined only by the claims of that patent.

What is claimed is:

1. A printed board comprising:
a base material, the base material comprising a first side and an opposing second side, the base material comprising a metal clad circuit pattern on at least one of the first side of the base material and the second side of the base material;
at least one dielectric applied to at least one of the first side of the base material and the second side of the base material;
wherein, the base material defines at least one via hole or comprises the at least one dielectric, the at least one via hole or the at least one dielectric providing access to a metal clad surface of an interconnect; and
a solder applied to the metal clad surface of the interconnect, such that the solder is bonded mechanically and electrically to the metal clad surface.

2. The printed board of claim 1, wherein:
when two or more structures of the printed board are laminated at a sufficient temperature; adjacent solders fuse or solders bond to metal clad surfaces forming printed board layer-to-layer interconnects.

3. The printed board of claim 1, wherein:
the base material comprises the metal clad circuit pattern on the first side of the base material or the second side of the base material.

4. The printed board of claim 1, wherein:
the base material defines the at least one via and comprises, or is directly connected to, the at least one dielectric.

5. A method comprising a plurality of activities, comprising:
fabricating a printed board;
drilling at least one blind via from at least one outer surface of the printed board;
applying a soldermask to the printed board;
applying a surface finish to the printed board; and
applying solder to the at least one blind via.

6. A method comprising a plurality of activities, comprising:
fabricating a sub-composite printed board;
laminating a dielectric layer and a metal clad layer to the sub-composite printed board;
imaging a metal clad circuit pattern;
drilling at least one blind via from at least one outer surface of the printed board;
applying a soldermask to the printed board;
applying a surface finish to the printed board; and
applying solder to the at least one blind via.
